(19) United States
(12) Patent Application Publication
(10) Pub. No.: US 2015/0333213 A1
(43) Pub. Date: Nov. 19, 2015

(54) DIAMOND-LIKE CARBON COATINGS FOR SUBSTRATE CARRIERS

(71) Applicant: Applied Materials, Inc., Santa Clara, CA (US)

(72) Inventors: Shuran SHENG, Cupertino, CA (US); Lin ZHANG, San Jose, CA (US); Su Ho CHO, Santa Clara, CA (US)

(21) Appl. No.: 14/698,395

(22) Filed: Apr. 28, 2015

Related U.S. Application Data
(60) Provisional application No. 62/000,376, filed on May 19, 2014.

(51) Int. Cl. H01L 31/18; C23C 16/505; C23C 16/26

(52) U.S. Cl. CPC H01L 31/1876; C23C 16/26; C23C 16/505

(57) ABSTRACT

A substrate carrier having a diamond-like carbon coating disposed thereon is provided. The diamond-like carbon coating may have the property of being substantially resistant to commonly used cleaning processes performed during the fabrication of photovoltaic cells, such as cleaning processes using an NF₃ plasma. Additionally, a method of forming a diamond-like carbon coating on a substrate carrier is provided. The method includes positioning a substrate carrier in a processing chamber and forming a diamond-like carbon coating thereon. Forming the diamond-like carbon coating includes flowing a carbon-containing gas into a processing chamber and dissociating the carbon-containing gas. Furthermore, a method of quick removal of diamond-like carbon coatings from processing chamber walls, processing chamber components, substrate carriers, and other objects is provided.

### PRIORITY

This application claims priority to U.S. provisional patent application Ser. No. 62/000,376, filed May 19, 2014, which is herein incorporated by reference.

### BACKGROUND

1. Field

Embodiments of the present disclosure generally relate to equipment for fabricating photovoltaic or solar cells.

2. Description of the Related Art

Photovoltaic (PV) cells are devices which convert sunlight into direct current (DC) electrical power. A typical PV cell includes a p-type silicon substrate, typically less than about 0.3 mm thick, with a thin layer of an n-type silicon material disposed on top of the p-type substrate. When exposed to sunlight, the p-n junction generates pairs of free electrons and holes. An electric field formed across a depletion region of the p-n junction separates the free holes from the free electrons, which may flow through an external circuit or electrical load. The voltage and current generated by the PV cell are dependent on the material properties of the p-n junction, the interfacial properties between deposited layers, and the surface area of the device.

Conventional methods of forming p-n junctions typically include forming the n-type and/or p-type layers via deposition processes, such as plasma enhanced chemical vapor deposition (PECVD). In order to increase the throughput of the deposition processes, multiple substrates are simultaneously processed by placing multiple substrates on a substrate carrier during deposition. However, conventional substrate carriers may suffer from short life spans. Additionally, deposition processes performed using substrate carriers may result in increased particle generation during deposition processes. Particle generation during deposition processes may lead to defective or low performance PV cells.

As the foregoing illustrates, there is a need in the art for improved substrate carriers.

### SUMMARY

A substrate carrier having a diamond-like carbon coating disposed thereon is provided. The diamond-like carbon coating may have the property of being substantially resistant to commonly used cleaning processes performed during the fabrication of photovoltaic cells, such as cleaning processes using an NF₃ plasma. Additionally, a method of forming a diamond-like carbon coating on a substrate carrier is provided. The method includes positioning a substrate carrier in a processing chamber and forming a diamond-like carbon coating thereon. Forming the diamond-like carbon coating includes flowing a carbon-containing gas into the processing chamber and dissociating the carbon-containing gas.

One embodiment of the present disclosure includes a substrate carrier. The substrate carrier includes a retaining frame, a sub-carrier retaining surface, and at least one sub-carrier retaining recess configured to laterally retain one or more sub-carriers. The substrate carrier also has a diamond-like carbon coating formed on the sub-carrier retaining surface.

Another embodiment of the present disclosure includes a method of coating a substrate carrier. The method includes positioning a substrate carrier in a processing chamber. The substrate carrier includes a retaining frame, a sub-carrier retaining surface, and at least one sub-carrier retaining recess configured to laterally retain one or more sub-carriers. The method further includes blanket depositing a diamond-like carbon coating over the sub-carrier retaining surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a processing chamber for processing a batch of substrates according to one embodiment of the present disclosure.

FIG. 2 is a top perspective view of a substrate carrier according to one embodiment described herein.

FIG. 3 is a top perspective view of a sub-carrier according to one embodiment described herein.

FIG. 4 is a flow diagram illustrating one embodiment of a method for depositing a coating.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

A substrate carrier having a diamond-like carbon coating disposed thereon is provided. The diamond-like carbon coating may have the property of being substantially resistant to commonly used cleaning processes performed during the fabrication of photovoltaic cells, such as cleaning processes using an NF₃ plasma. Additionally, a method of forming a diamond-like carbon coating on a substrate carrier is provided. The method includes positioning a substrate carrier in a processing chamber and forming a diamond-like carbon coating thereon. Forming the diamond-like carbon coating includes flowing a carbon-containing gas into a processing chamber and dissociating the carbon-containing gas.

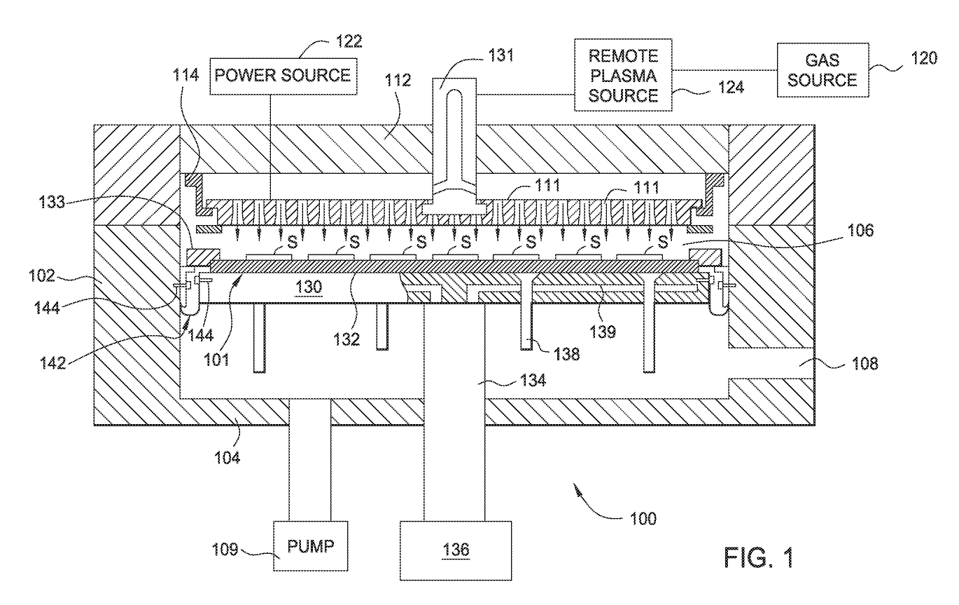

FIG. 1 is a schematic cross-sectional view of a processing chamber 100 for processing a batch of substrates according to one embodiment of the present disclosure. One suitable processing chamber that may benefit from the embodiments disclosed herein includes a processing chamber that is part of a Gen 2 to Gen 8.5 processing platform available from Applied Materials, Inc., located in Santa Clara, Calif. Other processing chambers and processing systems available from other manufacturers may likewise benefit from the embodiments disclosed herein.

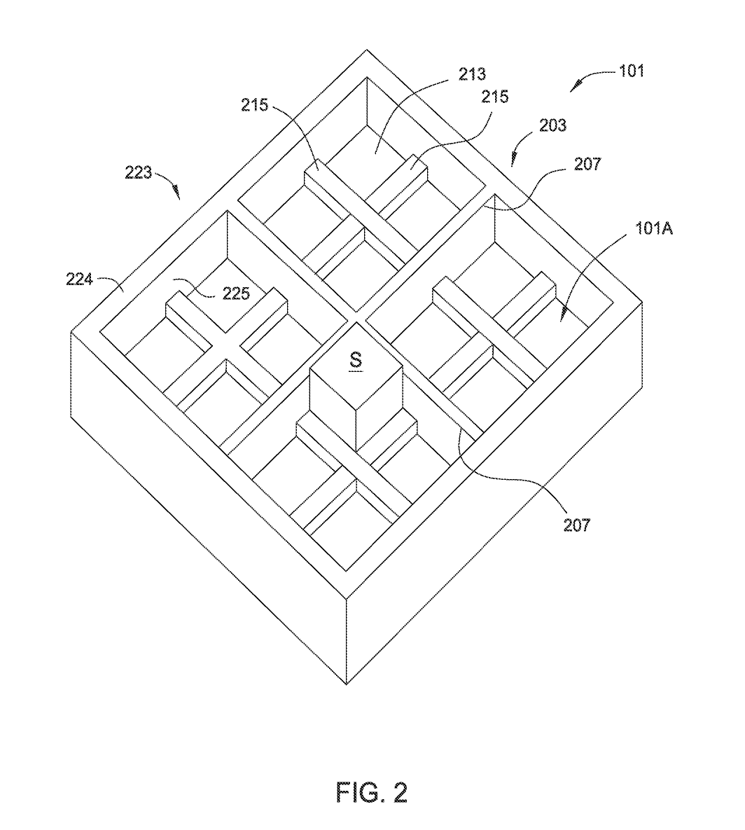

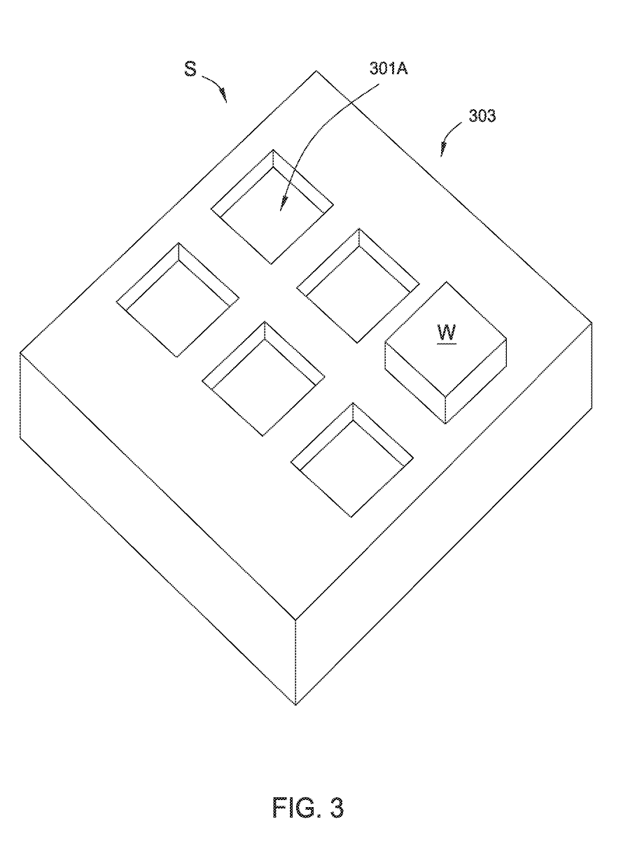

The processing chamber 100 generally includes walls 102, a bottom 104, a showerhead 110, and a substrate support 130, which define a process volume 106. The process volume 106 is accessed through an opening 108 such that a substrate carrier 101 may be transferred in and out of the processing chamber 100. The wafer carrier may have one or more sub-carriers S disposed thereon. Each sub-carrier S may have one or more substrates W (shown in FIG. 3) disposed thereon. The substrates W may be made of, for example, a glass or semiconductor material. The carrier 101 has at least one sub-carrier retaining recess 101A formed therein (shown in FIG. 2). The sub-carrier retaining recess 101A is configured to hold and retain the sub-carriers S during the transferring in and out of the processing chamber 100.

The substrate support 130 includes a substrate receiving surface 132 for supporting the carrier 101 and a stem 134 coupled to a lift system 136 to raise and lower the substrate support 130. A shadow frame 133 may be optionally placed over periphery of the carrier 101. Lift pins 138 are movably disposed through the substrate support 130 to move the carrier 101 to and from the substrate receiving surface 132. The substrate support 130 may also include heating and/or cooling elements 139 to maintain the substrate support 130 at a desired temperature. One or more grounding assemblies 142 are coupled to the walls 102, the substrate support 130, and/or other chamber components by attaching devices 144.

The showerhead 110 is coupled to a backing plate 112 at its periphery by a suspension 114. A gas source 120 is coupled to the backing plate 112 and provides gases through a tube 131, which passes through the backing plate 112. The gases exit the tube 131 and pass through a plurality of holes 111 in the showerhead 110 to enter the process volume 106. A vacuum pump 109 is coupled to the processing chamber 100 to control the process volume 106 at a desired pressure. A power source 122 is coupled to the backing plate 112 and/or to the showerhead 110 to provide power to the showerhead 110, creating an electric field between the showerhead 110 and the substrate support 130 and generating a plasma from the gases in the process volume 106. The power source 122 may be configured to supply, for example, RF or VHF power. The power source 122 may supply RF power at, for example, about 13.56 MHz. The power source 122 may supply VHF power at, for example, between about 20 MHz and about 300 MHz.

A remote plasma source 124, such as an inductively coupled remote plasma source, may optionally be coupled between the gas source 120 and the backing plate 112. The processing of batches of substrates W to form PV cells may include generating a plasma from a cleaning gas in the remote plasma source 124 and flowing the excited species generated from the plasma into the process volume 106. The cleaning gas may be further excited by the power source 122 provided to the showerhead 110. Suitable cleaning gases include but are not limited to NF₃, F₂, and SF₆.

FIG. 2 is a top perspective view of a representative embodiment of the carrier 101. As shown in FIG. 2, the carrier 101 includes a retaining frame 203 and 16 sub-carrier retaining recesses 101A. The retaining frame 203 includes exterior walls 223 and a sub-carrier retaining surface 213. The exterior walls 223 extend from the sub-carrier retaining surface 213 and have a top surface 224 and an interior surface 225. The height of the exterior walls 223, measured from the sub-carrier retaining surface 213, may be selected based on the dimensions of the one or more sub-carriers S to be supported on the sub-carrier retaining surface 213. The exterior wall height may be substantially the same as, greater than, or less than the height of the sub-carriers S. For example, in a configuration where the sub-carriers to be supported by the sub-carrier retaining surface 213 have dimensions 624 mm×624 mm×0.2 mm, the height of the exterior walls 223 may be from about 0.1 mm to about 0.3 mm.

As shown in FIG. 2, each sub-carrier retaining recess 101A is separated from each adjacent sub-carrier retaining recess 101A by a sub-carrier retaining wall member 215 or a retaining frame center bar 207. The sub-carrier retaining wall members 215 function to separate and retain the sub-carriers S on the carrier 101. Retaining frame center bars 207 function to separate the sub-carriers S on the carrier 101 and also function to provide structural stability to the carrier 101. In some embodiments, the retaining frame center bars 207 and the sub-carrier retaining wall members 215 are the same height. In other embodiments, the retaining frame center bars 207 and the sub-carrier retaining wall members 215 have different heights, for example, as shown in FIG. 2,

As shown in FIG. 2, a pair of intersecting sub-carrier retaining wall members 215 is positioned in each quadrant defined by the retaining frame center bars 207. In other embodiments, the pair of sub-carrier retaining wall members 215 may not intersect in the quadrant, or the pair of sub-carrier retaining wall members 215 may intersect at different angles than are shown in FIG. 2. In other embodiments, fewer than two sub-carrier retaining wall members 215 may be positioned in each quadrant. For example, one or zero retaining wall members 215 may be positioned in each quadrant. In other embodiments, more than two sub-carrier retaining wall members 215 may be positioned in each quadrant. In embodiments where more than two sub-carrier retaining wall members 215 are positioned in each quadrant, some of the sub-carrier retaining wall members 215 may intersect and others may not intersect. For example, the more than two sub-carrier retaining wall members 215 may form a grid. As shown, the interior surface 225 of the exterior walls 223, the sub-carrier retaining wall members 215, and the retaining frame center bars 207 have vertical edges extending from the sub-carrier retaining surface 213; however, in other embodiments, the edges may be sloped.

As shown in FIG. 2, the carrier 101 is configured to retain 16 sub-carriers S. In other embodiments, the carrier 101 may be configured to hold fewer or more than 16 sub-carriers S. For example, in one embodiment, the carrier 101 is configured to hold up to about thirty sub-carriers S at a time in a planar array. In one embodiment, the carrier 101 is configured to hold between about 2 and about 4 sub-carriers S at a time in a planar array.

In some embodiments, the carrier 101 does not have the sub-carrier retaining wall members 215. In other embodiments, the carrier 101 does not have retaining frame center bars 207. In embodiments where the carrier 101 does not have retaining frame center bars 207, the sub-carrier retaining wall members 215 may extend from one exterior wall 223 to an opposite exterior wall 223. In some embodiments, the carrier 101 has a top surface that is completely planar; i.e., the carrier 101 does not have exterior walls 223, retaining frame center bars 207, sub-carrier retaining wall members 215, or sub-carrier retaining recesses 101A. In other embodiments, the carrier 101 has a top surface that is completely planar and has a plurality of sub-carrier recesses 101A. The plurality of sub-carrier recesses 101A may have lateral dimensions of between about 125 mm to about 156 mm×about 125 mm to about 156 mm. The plurality of sub-carrier recesses 101A may have a depth of between about 0.2 mm to about 0.3 mm. In other embodiments, the dimensions of the plurality of sub-carrier recesses 101A may be larger or smaller.

As shown in FIG. 2, the carrier 101 is square. In other embodiments, the carrier 101 may be rectangular, circular, or have a different shape. As shown, the sub-carrier retaining surface 213 is substantially planar. In some embodiments, the sub-carrier retaining surface 213 is concave or convex. The carrier 101 may be made of aluminum, stainless steel, graphite, ceramics, carbon fiber, carbon fiber composite, other suitable materials, or combinations thereof. The carrier 101 may optionally include pins or bosses extending therefrom to retain the sub-carriers S thereon.

FIG. 3 is a top-perspective view of a representative sub-carrier S with a substrate W positioned thereon. As shown, the sub-carrier includes a retaining frame 303 and a plurality of substrate-retaining recesses 301A. Six substrate-retaining recesses 301A are shown, but other embodiments may include any number of substrate-retaining recesses 301A. For example, other embodiments may include up to about 100 substrate-retaining recesses 301A, for example, between 20 and 40 substrate-retaining recesses 301A. Other embodiments may include more than 100 substrate-retaining recesses 301A. The number of substrate-retaining recesses 301A to be included within the retaining frame 303 will depend on, for example, substrate size, sub-carrier size, carrier size, processing chamber size, substrate support surface size, and the desired number of substrates W to process in each batch.

The dimensions of the substrate-retaining recesses 301A will depend on the dimensions of the substrates W to be positioned within the substrate retaining recesses 301A. The lateral dimensions of the substrate retaining recesses 301A will be larger than the lateral dimensions of the substrate W. For example, each lateral dimension of the substrate-retaining recess 301A may be about 1 mm larger than each lateral dimension of the substrate W. The depth of the substrate-retaining recesses 301A may he between about 0.1 mm and about 3 mm deeper than the thickness of the substrate W.

The sub-carrier S may be made of aluminum, stainless steel, graphite, ceramics, carbon fiber, carbon fiber composite, other suitable materials, or combinations thereof. The sub-carrier S may optionally include pins or bosses extending therefrom to retain the substrate W thereon.

In one embodiment, the carrier 101 has a coating formed thereon. The coating may cover the retaining frame 203, the sub-carrier retaining surface 213, the sub-carrier retaining recesses 101A, the exterior walls 223, the optional retaining frame center bars 207, the optional sub-carrier retaining wall members 215, and/or the other surfaces of the carrier 101. The coating of the carrier 101 may be a diamond-like carbon coating. A diamond-like carbon coating includes a solid material having a mixture of sp³ and sp² bonds between carbon atoms. The thickness of the coating may be between about 0.1 μm and about 200 μm, such as between about 0.5 μm and about 20 μm, such as about 2 μm. The thickness of the coating may be substantially uniform across the sub-carrier retaining surface 213 and the other surfaces.

In some embodiments, the diamond-like carbon coating contains carbon and hydrogen. In other embodiments, the diamond-like carbon coating may contain carbon and hydrogen and also be doped with one or more heteroatoms. The inclusion of dopant atoms allows the properties of the diamond-like carbon coating to be tuned. The one or more heteroatoms may he, for example, nitrogen, boron, fluorine, titanium, tungsten, chromium, or combinations thereof. Doping with one or more of N, B, F, Ti, W, and Cr may improve the electrical, mechanical, thermal, or chemical properties of the diamond-like carbon coating. For example, nitrogen dopants may make the diamond-like carbon coating more similar to pure diamond, harder, and more conductive. Boron dopants may make the diamond-like carbon coating more resistant to oxidation, stabilize sp³ bonding, have reduced internal stress, and retain high hardness, low friction, and wear. Fluorine dopants may make the diamond-like carbon coating harder, more resistant to chemical attack, have a lower coefficient of friction (which may lead to less particle generation during processing), improve hydrophobic properties, and reduce hydrogen content and internal stress. In representative embodiments, the diamond-like carbon coating may contain one heteroatom selected from the group consisting of nitrogen, boron, fluorine, titanium, tungsten, and chromium, and the molar % of that dopant atom may be up to about 50 molar %, such as between about 10 molar % and about 40 molar %, such as about 30 molar %. In other embodiments, the diamond-like carbon coating may contain more than one heteroatom selected from the group consisting of nitrogen, boron, fluorine, titanium, tungsten, and chromium, and the total combined molar % of the dopant species may be up to about 50 molar %, such as between about 10 molar % and about 40 molar %, such as about 30 molar %.

The properties of the diamond-like carbon coatings can also be tuned based on the processing parameters. Representative properties of the coatings that can be tuned include the band gap, the refractive index, the extinction coefficient, the internal stress, the coefficient of friction, the etch rate, and the surface hardness. For example, representative properties of diamond-like carbon coatings comprising carbon and hydrogen can be tuned as follows. The band gap of the coatings can be tuned between about 0.9 eV and about 4 eV. The band gap was measured at 25° C. by spectroscopic ellipsometry. The refractive index can be tuned between about 1.5 and about 2.3. The refractive index was measured at 633 nm by spectroscopic ellipsometry. The extinction coefficient of the coatings can be tuned between about 0.01 and about 0.40. The extinction coefficient was measured at 400 nm by spectroscopic ellipsometry. The intrinsic stress of the coatings can be tuned between about −40×10⁹ dyne/cm² to about 1×10⁹ dyne/cm². The intrinsic stress was measured by a film stress measurement system, such as a KLA-Tencor Flexus tool.

Representative properties of diamond-like carbon coatings comprising carbon, hydrogen, and nitrogen can be tuned as follows. The band gap can be tuned between about 0.9 eV and about 1.8 eV. The refractive index can be tuned between about 1.8 and about 2.3. The extinction coefficient can be tuned between about 0.2 and about 0.40. The internal stress can he tuned between about −32×10⁹ dyne/cm² to about 0.9×10⁹ dyne/cm².

The diamond-like carbon coatings disclosed herein may also have a high etching resistance to conventional chamber cleaning processes, which will allow for the carriers 101 to have a longer lifespan. The fabrication of a PV cell requires a series of processing stages. In between processing stages, the processing chamber 100 may be cleaned, such as with a remotely generated NF₃ plasma. The carrier 101 may be positioned within the processing chamber 100 during the cleaning process. Thus, a carrier 101 that has a low etch resistance to cleaning plasmas, such as NF₃ plasmas, will have a short lifespan. Contrarily, a carrier 101 with a high etch resistance to conventional cleaning processes increases will have a long lifespan. An increased lifespan of carriers can decrease the cost of ownership for the fabrication facilities and increase throughput since less time and money will be consumed replacing carriers.

The experimental conditions for measuring NF₃ etch resistance may be as follows. Argon was flowed into a remote plasma source, such as remote plasma source 124, of a processing chamber, such as processing chamber 100. A plasma was then ignited in the remote plasma source 124. Then NF₃ was flowed into the remote plasma source 124, and the flow of argon was stopped. The flow rates per substrate surface area were between about 100 sccm/m² and about 10,000 sccm/m², such as about 5000 sccm/m². A plasma was generated from the NF₃ in the remote plasma source 124 from an RF power of about 6 kW. The radicals generated by the remote plasma source 124 were thereafter flowed into the processing volume 106, where the test carriers with the diamond-like carbon coatings were positioned. The etching was performed while the substrate support 130 was maintained at about 200° C. and the pressure of the processing chamber 100 was maintained at between about 100 mTorr to about 500 mTorr. The spacing was about 1500 mill. The test carriers had a surface area of about 4300 cm². The etch rate of the test carriers was as low as about 30 Å/hr.

Like the properties listed above, the etch rate of a carrier to an NF₃ plasma can also be tuned based on processing parameters and doping. For example, the etch rate to a NF₃ plasma can be tuned to be a substantially low. A substantially low NF₃ etch rate is defined herein to be less than about 50 Å/hr, measured by the conditions set forth above. The etch rate of diamond-like carbon coatings comprising carbon and hydrogen can be tuned between about 30 Å/hr and about 330 Å/hr. Fine tuning of the etch rate is possible. For example, the etch rate of diamond-like carbon coatings comprising carbon and hydrogen can be tuned between about 30 Å/hr and about 50 Å/hr. Diamond-like carbon coatings comprising carbon, hydrogen, and nitrogen can likewise be tuned to have a substantially low NF₃ etch rate while still having a high etch rate for silicon films, such as greater than about 400 Å/min.

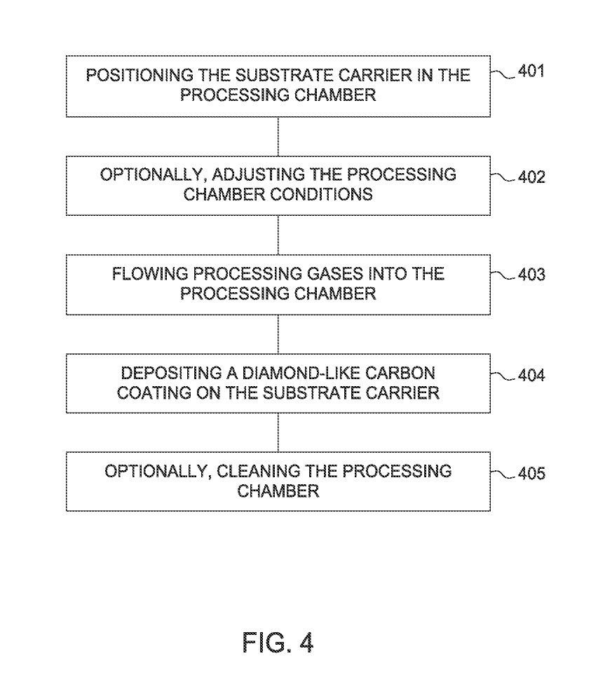

FIG. 4 depicts a flow diagram of one method for depositing a diamond-like carbon coating on the carrier 101. The method for depositing the diamond-like carbon coating on the carrier 101 has multiple stages. The stages can be carried out in any order or simultaneously (except where the context excludes that possibility), and the method can include one or more other stages which are carried out before any of the defined stages, between two of the defined stages, or after all the defined stages (except where the context excludes that possibility).

At stage 401, the carrier 101 is positioned in the processing chamber 100, such as on the substrate receiving surface 132 of the substrate support 130. For example, the carrier 101 may be positioned so that the sub-carrier retaining surface 213 is facing the showerhead 110. The carrier 101 may have no sub-carriers S positioned thereon. Alternatively, the carrier 101 may have one or more sub-carriers S positioned thereon. In some embodiments wherein the carrier 101 has sub-carrier retaining recesses 101A, at least one of the sub-carrier retaining recesses 101A does not have a sub-carrier S positioned thereon. In other embodiments, at least half of the sub-carrier retaining recesses 101A do not have a sub-carrier S positioned thereon. In some embodiments, the carrier 101 does not have a coating thereon prior to being positioned on the substrate receiving surface 132. For example, the carrier 101 may not have a diamond-like carbon coating thereon prior to being positioned on the substrate receiving surface 132. Alternatively, the carrier 101 may have a diamond-like carbon coating or another coating thereon prior to being positioned on the substrate receiving surface 132.

At optional stage 402, the processing chamber conditions are adjusted. The temperature of the substrate support 130 may be maintained at between about 50° C. and about 500° C., such as between about 200° C. and about 400° C., such as about 350° C. Alternatively, the substrate support 130 may be maintained at about 200° C. or about 380° C. The pressure of the processing chamber 100 may be maintained at between about 100 mTorr and about 10000 mTorr, such as between about 500 mTorr and about 5000 mTorr. In other embodiments, the pressure of the processing chamber 100 may be maintained between about 200 mTorr and about 750 mTorr. The spacing may be between about 400 mil and about 1200 mil, such as between about 600 mil and about 1000 mil, such as about 800 mil. In some embodiments, the processing chamber conditions may be adjusted prior to positioning the carrier 101 in the processing chamber 100.

At stage 403, processing gases are flowed into the processing chamber 100. The processing gases may include, for example, carbon-containing gases, dopant gases, and inert gases. A carbon-containing gas is flowed into the process volume 106 from the gas source 120. The carbon-containing gas may include one or more hydrocarbon gases, such as one or more alkanes, one or more alkenes, one or more alkynes, one or more aromatic hydrocarbons, or combinations thereof. Representative alkanes include methane, ethane, propane, isobutane, cyclopentane, cyclohexane, and methylcylohexane. Representative alkenes include ethylene, propylene, 1-butene, (Z)-2-butene, (E)-2-butene, isobutylene, and cyclohexene. Representative alkynes include acetylene, propyne, and 1-butyne. Representative aromatic hydrocarbons include benzene, naphthalene, toluene, and xylene. The carbon-containing gas may be flowed at a flow rate per carrier surface area of between about 500 sccm/m² and about 5000 sccm/m², such as about 2000 sccm/m².

A dopant gas may optionally be flowed into the process volume 106 from the gas source 120. The dopant gas may contain nitrogen atoms, boron atoms, fluorine atoms, titanium atoms, tungsten atoms, chromium atoms, other atoms, or combinations thereof. Representative nitrogen dopant gases include nitrogen, ammonia, and hydrazine. Representative boron dopant gases include diborane, trimethyl boron, and boron trifluoride. Representative fluorine dopants include NF₃, SF₆, SF₄, F₂, CF₄, and CF₂F₆. Representative titanium dopant gases include titanium isopropoxide (Ti[OCH₂CH₃]₄). In other embodiments, the carbon-containing gas may also contain the dopant atom, such as in an in situ doping process. For example, methylamine or trimethylamine may be used to dope with nitrogen. The dopant gas may be flowed at a flow rate per carrier surface area of between about 180 sccm/m² and about 2000 sccm/m², such as about 500 sccm/m². In other embodiments, the diamond-like carbon coating can be doped after deposition, such as by an ion implantation process or a diffusion process.

An inert gas may also be flowed into the process volume 106 from the gas source 120. The inert gas may be argon, hydrogen, helium, neon, other suitable gases, or combinations thereof. The inert gas may be flowed at a flow rate per substrate surface area of between about 500 sccm/m² and about 10000 sccm/m², such as about 4000 sccm/m².

In some embodiments, the mixture of gases flowing into the processing chamber 100 includes only the carbon-containing gas or gases and the inert gas or gases. In other embodiments, the mixture of gases flowing into the processing chamber 100 consists essentially of the carbon-containing gas or gases and the inert gas or gases. In some embodiments, the mixture of gases flowing into the processing chamber 100 includes only the carbon-containing gas or gases, the inert gas or gases, and the dopant gas or gases. In other embodiments, the mixture of gases flowing into the processing chamber 100 consists essentially of the carbon-containing gas or gases, the inert gas or gases, and the dopant gas or gases. In other embodiments, gases in addition to the carbon-containing gas or gases, the dopant gas or gases, and the inert gas or gases may be flowed into the processing chamber 100.

At stage 404, a diamond-like carbon coating is deposited on the carrier 101. In one embodiment, the power source 122 provides either a radio frequency (RF) power or a very high frequency (VHF) power to the showerhead 110 through the backing plate 112. The RF power may have a frequency of, for example, about 13.56 MHz. The VHF power may have a frequency of, for example, between about 20 MHz and about 150 MHz, such as about 27 MHz or about 40 MHz. In other embodiments, the VHF power may be higher than about 40 MHz. The applied power may be between about 0.2 W/cm² and about 1.0 W/cm². The applied power may ignite a plasma in the process volume 106 from gases flowed therein. The plasma may activate the gases in the process volume 106. The chemical bonds of the carbon-containing gases and/or the optional dopant gases may be dissociated by the applied power and/or the active species generated by the ignited plasma. In embodiments where a dopant gas is used, the carbon-containing gas may react to form a bond between a carbon atom of the carbon-containing gas and a heteroatom of the dopant gas. The dissociated and/or activated species may combine to deposit a diamond-like carbon coating on the carrier 101. For example, the diamond-like carbon coating may be blanket deposited on the carrier 101. The diamond-like carbon coating may be conformally deposited over the carrier 101. The power may continue to be applied until the diamond-like carbon coating reaches the desired thickness. For example, the power may continue to be applied until the thickness of the coating is between about 0.1 μm and about 200 μm, such as between about 0.5 μm and about 20 μm, such as about 2 μm. After the diamond-like carbon coating is deposited to the desired thickness, the carrier 101 may be removed from the processing chamber 100.

In an alternative embodiment, a plasma may be generated from the inert gas in a remote plasma source, such as remote plasma source 124, and the reactive species may thereafter be flowed into the process volume 106 to deposit the diamond-like carbon coating. In other embodiments, the plasma may be generated by other methods, such as by an inductively coupled plasma source or by a microwave generator.

As mentioned above, the properties of the diamond-like carbon coating can be tuned by varying the processing conditions. For example, diamond-like carbon coatings deposited using CH₄ as the carbon-containing gas with a flow rate of about 2000 sccm/m² and argon as the inert gas with a flow rate of about 4000 sccm/m² have the following properties when deposited according to the following conditions. The properties described below were determined using the techniques described above. When the pressure was 200 mTorr, the applied power was 1.2 kW, and the substrate support temperature was 200° C.; the deposition rate was about 60 Å/min; the band gap was 1.8 eV; the refractive index (measured at 633 nm) was about 2.0; the extinction coefficient (measured at 400 nm) was about 0.24; the internal stress was about −10.7×10⁹ dyne/cm²; and the NF₃ etch rate was about 330 Å/hr.

When the pressure was 9 Torr, the applied power was 3 kW, and the substrate support temperature was 200° C.; the deposition rate was about 460 Å/min; the band gap was about 3.8 eV; the refractive index (measured at 633 nm) was about 1.5, the extinction coefficient (measured at 400 nm) was about 0.006; and the internal stress was about 0.19×10⁹ dyne/cm².

When the pressure was 200 mTorr, the applied power was 1.2 kW, and the substrate support temperature was 380° C.; the deposition rate was about 30 Å/min; the band gap was about 1.6 eV; the refractive index (measured at 633 nm) was about 2.2; the extinction coefficient (measured at 400 nm) was about 0.30; the internal stress was about −32×10⁹ dyne/cm²; and the NF₃ etch rate was about 150 Å/hr.

When the pressure was 750 mTorr, the applied power was 1.6 kW, and the substrate support temperature was 380° C.; the deposition rate was about 30 Å/min; the band gap was about 1.5 eV; the refractive index (measured at 633 nm) was about 2.1; the extinction coefficient (measured at 400 nm) was about 0.40; the internal stress was about −30×10⁹ dyne/cm²; and the NF₃ etch rate was about 30 Å/hr.

When the pressure was 9 Torr, the applied power was 3 kW, and the substrate support temperature was 380° C.; the deposition rate was about 140 Å/min; the band gap was about 1.6 eV; the refractive index (measured at 633 nm) was about 2.1; the extinction coefficient (measured at 400 nm) was about 0.30; and the internal stress was about 0.18×10⁹ dyne/cm².

When the pressure was 5 Torr, the applied power was 3 kW, and the substrate support temperature was 380° C.; the deposition rate was about 520 Å/min; the band gap was about 1.7 eV; the refractive index (measured at 633 nm) was about 1.8; the extinction coefficient (measured at 400 nm) was about 0.21; and the internal stress about was 0.26×10⁹ dyne/cm².

In a nitrogen-doped diamond-like carbon coating deposited using CH₄ as the carbon-containing gas with a flow rate of 4000 sccm/m², nitrogen as the dopant gas at a flow rate of 1500 sccm/m², and argon as the inert gas at a flow rate of 8000 sccm/m², the following properties were obtained from the following conditions. When the pressure was 750 mTorr, the applied power was 1.6 kW, and the substrate support temperature was 380° C.; the deposition rate was about 14 Å/min; the band gap was about 1.7 eV; the refractive index (measured at 633 nm) was about 2.3; the extinction coefficient (measured at 400 nm) was about 0.40; the internal stress was about −30×10⁹ dyne/cm²; and the NF₃ etch rate was about 50 Å/hr. When the pressure was 5 Torr, the applied power was 3 kW, and the substrate support temperature was 380° C.; the deposition rate was about 60 Å/min; the band gap was about 0.92 eV; the refractive index (measured at 633 nm) was about 1.8; the extinction coefficient (measured at 400 nm) was about 0.32; and the internal stress was about 0.89×10⁹ dyne/cm².

At optional stage 405, a cleaning process may be performed in the processing chamber 100 to remove any diamond-like carbon deposits that may have formed on the processing chamber was or components. The cleaning process may be performed after the carrier 101 is removed from the processing chamber 100. Alternatively, the cleaning process may be performed while the carrier 101 remains in the processing chamber 100.

During the cleaning process, the processing chamber conditions may be adjusted. For example, the temperature of the substrate support 130 may be maintained at between about 100° C. and about 500° C., such as between about 200° C. and about 400° C., such as about 300° C. The pressure of the processing chamber 100 may be maintained at between about 100 mTorr and about 1000 mTorr, such as between about 200 mTorr and about 500 mTorr, such as about 250 mTorr. The spacing may be between about 1000 mil and about 2000 mil, such as between about 1200 mil and about 1600 mil, such as about 1500 mil. In other embodiments, the spacing may be between about 4000 mil and about 5000 mil, such as between about 4200 mil and about 4800 mil, such as about 4500 mil.

During the cleaning process, gases may be flowed into the remote plasma source 124 and then into the process volume 106 of the processing chamber 100. For example, one or more of N₂O, NF₃, Ar, N₂, and O₂ may be flowed into the remote plasma source 124. In one embodiment, a mixture of N₂O, NF₃, Ar, and N₂ is flowed into the remote plasma source 124 from the gas source 120. In an embodiment having a chamber volume of 144 liters, the flow rates may be as follows. N₂O may be flowed into the remote plasma source 124 from the gas source 120 at a flow rate per processing chamber volume of between about 1 sccm/liter and about 50 sccm/liter, such as about 10 sccm/liter. NF₃ may also be flowed into the remote plasma source 124 from the gas source 120 at a flow rate per processing chamber volume of between about 1 sccm/liter and about 30 sccm/liter, such as about 3 sccm/liter. Argon may also be flowed into the remote plasma source 124 from the gas source 120 at a flow rate per processing chamber volume of between about 1 sccm/liter and about 30 sccm/liter, such as about 5 sccm/liter. N₂ may also be flowed into the remote plasma source 124 from the gas source 120 at a flow rate per processing chamber volume of between about 1 sccm/liter and about 30 sccm/liter, such as about 5 sccm/liter. Additional gases may also be flowed into the remote plasma source 124.

In another embodiment, O₂ may be used in addition to or in place of N₂O. For example, O₂ may be flowed into the remote plasma source 124 from the gas source 120 at a flow rate per processing chamber volume of between about 1 sccm/liter and about 50 sccm/liter, such as about 10 sccm/liter.

To generate reactive species to perform the cleaning process, a power may be applied to the remote plasma source 124 from a power source (not shown). For example, the power applied to the remote plasma source may be between about 4 kW and about 8 kW, such as between about 5 kW and about 7 kW, such as about 6 kW.

An RF power may also be applied to the showerhead 110 by the power source 122. The power source 122 may supply RF power at, for example, about 13.56 MHz. The applied RF power may be between about 1 kW and about 2 kW, such as about 1.5 kW. In another embodiment, the power may be between 2 kW and about 4 kW, such as about 3 kW. For example, if the spacing is about 1500 mil, the applied RF power may be about 1.5 kW. In another example, if the spacing is about 4500 mil, the applied power may be about 3 kW. In another embodiment, the RF power is applied to the backing plate 112 instead of or in addition to being applied to the showerhead 110.

Embodiments of the cleaning process disclosed herein have demonstrated a very high etch rate to the diamond-like carbon deposits formed on the walls of the processing chamber 100 and the components of the processing chamber 100. The measured etch rate of one embodiment is greater than about 4400 Å/minute. Compared to processes using only NF₃ or only NF₃ and argon, the etch rate of the measured embodiment is about 3500 times faster and about 4 times faster, respectively.

In alternative embodiments, the cleaning process is used to remove a diamond-like carbon coating from a carrier 101. In some embodiments, a new diamond-like carbon coating may be applied to the carrier 101 after the diamond-like carbon coating is removed. In other embodiments, a different coating may be applied to the carrier 101 after the diamond-like carbon coating is removed. In some embodiments, the cleaning process disclosed herein is used to clean diamond-like carbon deposits formed on the walls of the processing chamber 100 from processes other than depositing a diamond-like carbon coating on a substrate carrier 101.

The previously described embodiments have many advantages, including the following. The diamond-like carbon coatings can be deposited on the carriers in the same processing chambers used to process the substrates. The diamond-like carbon coatings have a very high etch resistance to NF₃ plasma, which the carriers may be exposed to during processing the substrates. The NF₃ etch resistance leads to a dramatic increase in the lifespan of the carriers. The diamond-like carbon coatings have a very low coefficient of friction and very high surface hardness, which will result in minimal wafer surface damage, low particle generation, and high wear resistance. Through doping and/or varying processing conditions, the electrical, mechanical, thermal, and chemical properties of the diamond-like carbon coatings can be readily tuned. Moreover, by depositing a diamond-like carbon coating over conventional carriers, such as graphite carriers, the particles generated during processing can be reduced. Additionally, by depositing the diamond-like carbon coating over a porous or other carrier, outgassing of the carrier during deposition processes can be reduced. Embodiments disclosed herein also allow for quick removal of diamond-like carbon coatings from processing chamber walls, processing chamber components, substrate carriers, and other objects. The aforementioned advantages are illustrative and not limiting. It is not necessary for all embodiments to have all the advantages.

While the foregoing is directed to embodiments of the disclosure, other and further embodiments of the disclosure may be devised without departing from the basic scope thereof, and the scope thereof is determined by the claims that follow.

What is claimed is:

1. A substrate carrier comprising:
a retaining frame;
a sub-carrier retaining surface;
at least one sub-carrier retaining recess configured to laterally retain one or more sub-carriers; and
a diamond-like carbon coating formed on the sub-carrier retaining surface.

2. The substrate carrier of claim 1, wherein the diamond-like carbon coating has a thickness between about 0.1 μm and about 200 μm.

3. The substrate carrier of claim 2, wherein the substrate carrier comprises at least one retaining frame center bar.

4. The substrate carrier of claim 2, wherein the thickness of the diamond-like carbon coating is substantially uniform across the sub-carrier retaining surface.

5. The substrate carrier of claim 2, wherein the diamond-like carbon coating comprises dopant atoms selected from the group consisting of boron, nitrogen, fluorine, titanium, tungsten, chromium, and combinations thereof, and wherein the molar % of dopants is up to about 30 molar %.

6. The substrate carrier of claim 2, wherein the diamond-like carbon coating comprises up to about 30 molar % boron.

7. The substrate carrier of claim 2, wherein the diamond-like carbon coating comprises up to about 30 molar % titanium.

8. The substrate carrier of claim 2, wherein the diamond-like carbon coating comprises up to about 30 molar % nitrogen.

9. The substrate carrier of claim 2, wherein the diamond-like carbon coating comprises up to about 30 molar % fluorine.

10. A method of coating a substrate carrier, the method comprising:
positioning a substrate carrier in a processing chamber, wherein the substrate carrier comprises a retaining frame, a sub-carrier retaining surface, at least one sub-carrier retaining recess configured to laterally retain one or more sub-carriers positioned thereon; and
blanket depositing a diamond-like carbon coating over the sub-carrier retaining surface.

11. The method of claim 10, wherein the blanket depositing comprises:
flowing into the processing chamber a carbon-containing gas selected from the group consisting of one or more alkanes, one or more alkenes, one or more alkynes, one or more aromatic hydrocarbons, or mixtures thereof; and
dissociating at least some of the chemical bonds of the carbon-containing gas.

12. The method of claim 11, wherein the blanket depositing further comprises flowing into the processing chamber an inert gas.

13. The method of claim 11, wherein the carbon-containing gas comprises acetylene.

14. The method of claim 11, wherein the carbon-containing gas comprises CH₄.

15. The method of claim 11, further comprising:
flowing into the processing chamber a dopant gas comprising at least one heteroatom selected from the group consisting of B, N, Ti, W, Cr, and F; and
reacting the carbon-containing gas with the dopant gas.

16. The method of claim 12, further comprising:
flowing into the processing chamber nitrogen or ammonia; and
reacting the carbon-containing gas with the nitrogen or ammonia,

17. The method of claim 16, wherein the carbon-containing gas comprises acetylene.

18. The method of claim 17, wherein the carrier comprises aluminum, graphite, carbon fiber, carbon fiber composite, or stainless steel

19. The method of claim 18, wherein the inert gas is selected from the group consisting of argon, helium, hydrogen, and combinations thereof.

20. The method of claim 10, further comprising:
generating reactive species in a remote plasma source from a gas mixture, wherein the gas mixture comprises:
NF₃;
one or more of Ar and N₂; and
one or more of N₂O and O₂;
introducing the reactive species into the processing chamber; and
applying an RF power to a showerhead or a backing plate of the processing chamber.
